(19) United States
(12) Patent Application Publication
(10) Pub. No.: US 2023/0064539 A1
(43) Pub. Date: Mar. 2, 2023

(54) HEAT DISSIPATERS FOR VOLTAGE REGULATORS

(71) Applicant: HEWLETT-PACKARD DEVELOPMENT COMPANY, L.P., Spring, TX (US)

(72) Inventors: Andrew L. Wiltzius, Fort Collins, CO (US); Robert Lee Crane, Fort Collins, CO (US); Shane Ward, Fort Collins, CO (US)

(73) Assignee: HEWLETT-PACKARD DEVELOPMENT COMPANY, L.P., Spring, TX (US)

(21) Appl. No.: 17/794,437

(22) PCT Filed: Feb. 21, 2020
(86) PCT No.: PCT/US2020/019164

§ 371 Date: Jul. 21, 2022

(51) Int. Cl. H05K 7/20

(52) U.S. Cl. CPC H05K 7/209

(57) ABSTRACT

A voltage regulator assembly can include a voltage regulator to provide power to a processor. The voltage regulator can occupy a volumetric space and includes a voltage regulator component grouping within the volumetric space. The voltage regulator assembly can include a heat dissipater with a heat absorption end portion thermally coupled to the voltage regulator. The heat dissipater can be routed along the voltage regulator and into an enlarged spacing between the voltage regulator component groupings. The heat absorption end portion of the heat dissipater can be positioned within the volumetric space of the voltage regulator. The heat dissipater can include a heat rejection end portion that is routed outside of the volumetric space of the voltage regulator.

### BACKGROUND

Heat transfer devices can use the principles of thermal conductivity and phase transition to transfer heat between two solid interfaces. For example, at a hot interface of a heat transfer device, a liquid in contact with a thermally conductive solid surface can turn into a vapor by absorbing heat from that surface. The vapor can travel along the heat transfer device (e.g., along a heat pipe or heat tube) to a cold interface and can condense back into a liquid, where latent heat can be released. The liquid can return to the hot interface through capillary action, centrifugal force, or gravity, and the cycle can be repeated. Heat transfer devices are used in computer systems to move heat away from components such as central processing units (CPUs) and graphics processing units (GPUs) to heat sinks where thermal energy can be dissipated into a surrounding environment.

### BRIEF DESCRIPTION OF THE DRAWINGS

FIG. 1 schematically illustrates an example of a top view of a voltage regulator assembly having a voltage regulator and a heat dissipater to draw heat away from the voltage regulator in accordance with the present disclosure;

FIG. 2 schematically illustrates an example of a side view of a voltage regulator assembly having a voltage regulator and a heat dissipater to draw heat away from the voltage regulator in accordance with the present disclosure;

FIG. 3 schematically illustrates an example of a system that includes a voltage regulator and a heat dissipater in accordance with the present disclosure; and

FIG. 4 is a flowchart illustrating an example method of making a heat-dissipating voltage regulator assembly in accordance with the present disclosure.

### DETAILED DESCRIPTION

The present disclosure describes a voltage regulator assembly, a system, and a method of making a voltage regulator assembly. The voltage regulator assembly can include a voltage regulator to provide power to a processor. The voltage regulator can occupy a volumetric space and includes a voltage regulator component grouping within the volumetric space. The voltage regulator assembly can include a heat dissipater which includes a heat absorption end portion thermally coupled to the voltage regulator. The heat dissipater can be routed along the voltage regulator and into an enlarged spacing between the voltage regulator component groupings. The heat absorption end portion of the heat dissipater can be positioned within the volumetric space of the voltage regulator. The heat dissipater can include a heat rejection end portion that is routed outside of the volumetric space of the voltage regulator. In one example, the voltage regulator assembly can include a second heat dissipater including a second heat absorption end portion and a second heat rejection end portion. The heat absorption end portion of the heat dissipater can be routed along a first voltage regulator component grouping and the second heat absorption end portion of the second heat dissipater can be routed along a second voltage regulator component grouping. In another example, an individual voltage regulator component grouping can include, but is not limited to, an inductor, a capacitor, a driver and a metal-oxide-semiconductor field-effect transistor (MOSFET), and the individual voltage regulator component grouping can provide a portion of power to the processor and another individual voltage regulator component grouping can provide a second portion of power to the processor. In yet another example, the voltage regulator component groupings can independently include an average component spacing between individual voltage regulator components, where the enlarged spacing between the voltage regulator component groupings can be from 3 to 30 times greater than the average component spacing. In a further example, the volumetric space of the voltage regulator can be adjacent to a Peripheral Component Interconnect Express (PCIe) expansion card, and the heat absorption end portion of the heat dissipater within the volumetric space of the voltage regulator and the heat rejection end portion that is routed outside of the volumetric space may not interfere with the PCIe expansion card. In yet a further example, the heat rejection end portion can be oriented orthogonally relative to the heat absorption end portion.

In another example, a system can include a circuit board and a processor coupled to the circuit board. The system can include a voltage regulator to provide power to the processor, and the voltage regulator can occupy a volumetric space and includes a first voltage regulator component grouping and a second voltage regulator component grouping within the volumetric space. The system can include a heat dissipater to draw heat away from the voltage regulator and protect a graphics card configured to be coupled to the circuit board. The heat dissipater can be routed along the voltage regulator and into an enlarged spacing between the first voltage regulator component grouping and the second voltage regulator component grouping. The heat dissipater can include a heat absorption end portion thermally coupled to the voltage regulator and within the volumetric space of the voltage regulator which is adjacent to the graphics card. The heat dissipater can also include a heat rejection end portion that is routed outside of the volumetric space of the voltage regulator. The heat rejection end portion can be non-coplanar relative to the heat absorption end portion. In one example, the system can include a second heat dissipater including a second heat absorption end portion and a second heat rejection end portion. The heat absorption end portion of the first heat dissipater can be routed along the first voltage regulator component grouping and the second heat absorption end portion of the second heat dissipater can be routed along the second voltage regulator component grouping. In another example, the first and second voltage regulator component groupings can independently include an average component spacing between individual voltage regulator components, where the enlarged spacing between the first and second voltage regulator component groupings can be from 3 to 30 times greater than the average component spacing. In yet another example, the volumetric space of the voltage regulator can occupy a space between the circuit board and the graphics card. In a further example, the heat rejection end portion can be oriented orthogonally relative to the heat absorption end portion.

In another example, a method of making a heat-dissipating voltage regulator assembly can include dividing a voltage regulator into voltage regulator component groupings to leave an enlarged spacing therebetween relative to an average component spacing of individual voltage regulator component groupings. The method can include thermally coupling a heat absorption end portion of a heat dissipater with the voltage regulator and routing the heat dissipater into the enlarged spacing, where the heat absorption end portion coupled with the voltage regulator can be within a volumetric space of the voltage regulator. The method can include routing a heat rejection end portion of the heat dissipater outside of the volumetric space of the voltage regulator to a position where the heat rejection end portion can be non-coplanar relative to the heat absorption end portion. In one example, the method can further include thermally coupling a second heat absorption end portion of a second heat dissipater with the voltage regulator and routing the second heat dissipater into the enlarged spacing, where the second heat absorption end portion coupled with the voltage regulator can be within the volumetric space of the voltage regulator, and routing a second heat rejection end portion of the second heat dissipater outside of the volumetric space of the voltage regulator to a position where the second heat rejection end portion is non-coplanar relative to the second heat absorption end portion. In another example, the enlarged spacing can be from 3 to 30 times greater than the average component spacing of the individual voltage regulator component groupings. In yet another example, the method can further include positioning the voltage regulator so that the volumetric space of the voltage regulator occupies a space between a circuit board and a Peripheral Component Interconnect Express (PCIe) expansion card.

In these examples, it is noted that when discussing the voltage regulator assembly, the system, or the method, any of such discussions can be considered applicable to the other examples, whether or not they are explicitly discussed in the context of that example. Thus, for example, in discussing details about a voltage regulator assembly, such discussion also relates to the systems and methods described herein, and vice versa.

In some processor configurations, peripheral component interconnect express (PCIe) expansion cards have been moved closer to central processing unit (CPU) sockets to create a chassis that can fit many PCIe expansion cards (e.g., graphics cards), and in some instances, to fit as many PCIe expansion cards as possible. A voltage regulator cooling solution (e.g., a heat dissipater such as a heat pipe) can be employed to provide cooling to a voltage regulator that provides power to the CPU. The heat dissipater can contribute to performance as CPU power continues to increase, and voltage regulator cooling can also be useful for maintaining a maximum CPU frequency and enabling overclocking. The heat dissipater can draw heat away from the voltage regulator, thereby protecting the voltage regulator as well as the PCIe expansion card that is in physical proximity to the voltage regulator cooling solution. In the latest processor configurations, multiple components compete for valuable space on a circuit board, as the PCIe expansion card can be located in physical proximity to the CPU to achieve improved performance, and the high powered voltage regulator having the heat dissipater can also be located in physical proximity to the CPU.

In one example, the reduced size dimensions between the PCIe expansion card and the CPU can create issues with a z-height of the heat dissipater, where the z-height is a distance normal to a plane of the circuit board. More specifically, the reduced size dimensions between the PCIe expansion card and the CPU can make it difficult to place the heat dissipater for the voltage regulator beneath the PCIe expansion card. Further, with the reduced size dimensions, placing a second heat dissipater beneath the PCIe expansion card to handle an increased amount of heat generated by the more powerful CPU found in the recent processor configurations is even more difficult.

In the present technology, a low profile or reduced profile voltage regulator cooling solution is described, such as a low profile heat dissipater for the voltage regulator. The heat dissipater can be low profile or have a reduced profile in order to fit adjacent to the PCIe expansion card, thereby adhering to reduced size dimensions found in processor configurations. The low profile voltage regulator cooling solution can also support a second low profile heat dissipater for the voltage regulator. The two heat dissipaters can be embedded within a three-dimensional volumetric space of the voltage regulator, such that the two heat dissipaters can fit adjacent to the PCIe expansion card. Further, the two heat dissipaters can be routed along components in the voltage regulator and into an enlarged spacing between the components in the voltage regulator within the volumetric space of the voltage regulator, thereby enabling two heat dissipaters to be used to cool the voltage regulator without effecting the PCIe expansion card that is located in physical proximity to the low profile heat dissipaters.

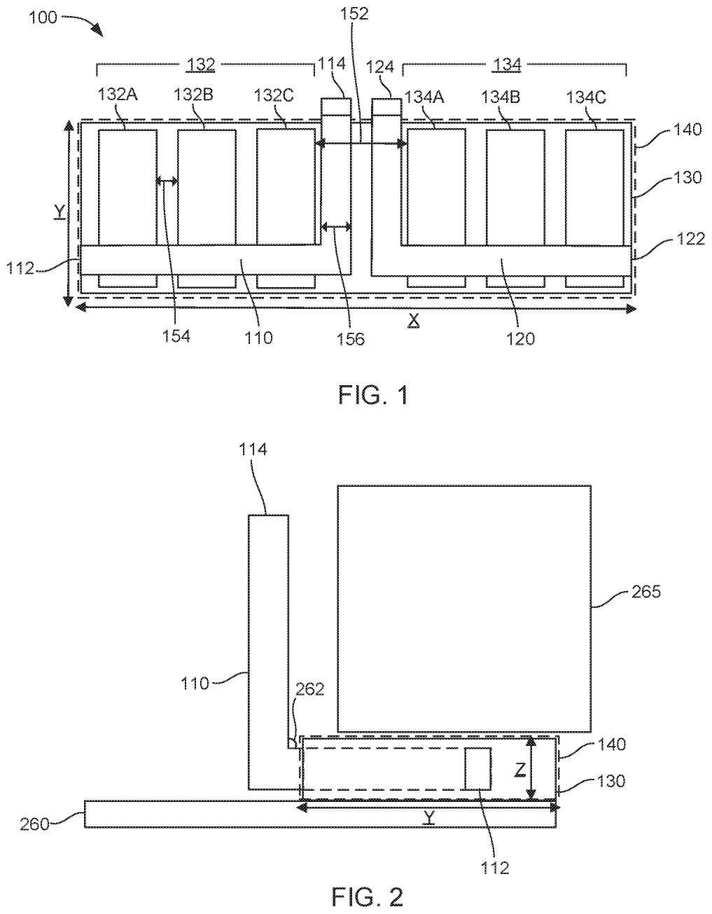

FIG. 1 illustrates an example of a top view of a voltage regulator assembly 100 having a voltage regulator 130 and a first heat dissipater 110 and a second heat dissipater 120 to draw heat away from the voltage regulator. In this example, the first and second heat dissipaters can be heat pipes. The voltage regulator may provide power to a processor (not shown in FIG. 1). The voltage regulator can include multiple voltage regulator component groupings, such as a voltage regulator component grouping 132A, 132B, and 132C, and a second voltage regulator component grouping 134A, 1348, and 134C. Notably, the voltage regulator component grouping may be referred to as either a “first voltage regulator component grouping” or simply as a “voltage regulator component grouping.” Sometimes the term “first” is used to describe multiple groupings, e.g., a first and a second voltage regulator component grouping. However, these two groupings can be referred to simply as a voltage regulator component grouping and a second voltage regulator component grouping. In addition to one grouping or two groupings (as shown in FIG. 1), there may be additional voltage regulator component groupings (not shown) as well. In one example, the voltage regulator assembly may employ a cooling solution to provide cooling to the voltage regulator, where the cooling solution can include the first heat dissipater and the second heat dissipater to draw heat away from the voltage regulator, thereby protecting surrounding components from the heat generated by the voltage regulator.

In one example, the volumetric space 140 of the voltage regulator assembly 100 is defined as the smallest rectangular volumetric space in an X-length dimension, a Y-width dimension, and a Z-height dimension that contains the voltage regulator assembly components, such as the inductor, capacitor, driver, MOSFET, and heat absorption end of each heat dissipater. In other words, the components of the voltage regulator assembly (e.g., the inductor, capacitor, driver, MOSFET, and heat absorption end of each heat dissipater) are within the volumetric space of the voltage regulator assembly. In one example, the Z-height dimension of the volumetric space 140 can include the voltage regulator assembly components, as well as a heat spreading plate and thermal interface. For example, the heat spreading plate may be inserted on top of capacitors and inductors in an individual voltage regulator component grouping. The inductors and capacitors can be taller than the drivers and MOSFETs (e.g., 10-13 mm tall versus 1.0-1.8 mm tall). So, an enlarged gap 152 between voltage regulator component groupings can be used to keep the heat absorption ends of the heat dissipaters within (or nearly within) the Z-height of the capacitors and inductors.

In one example, in the low profile voltage regulator cooling solution described herein, a heat absorption end of a heat dissipater (e.g., heat pipe) can be within the Z-height of the taller components (e.g., capacitors and inductors) with the heat spreading plate on top of the capacitors and inductors. The heat absorption end of the heat dissipater can be thermally coupled to the heat spreading place on top of the taller components. In the low profile design, the heat dissipater may not be placed on top of the taller components, but rather can run through the enlarged gap 152 between voltage regulator component groupings. In the low profile design, the heat spreading plate and the thermal interface can be placed on top of the taller components or against the sides of these taller components, such that the heat absorption ends of the heat dissipater can be thermally coupled to the heat spreading plate but can remain below the Z-height of the top of the heat spreading plate. In contrast, in a non-low-profile design, the heat absorption end of the heat dissipater would be placed across the top of the inductors and capacitors, which would add to the Z-height of the voltage regulator assembly 100.

In one example, the first heat dissipater 110 and the second heat dissipater 120 can be routed along and/or within their respective voltage regulator component groupings in the X-length dimension, and into the enlarged spacing 152 between voltage regulator component groupings in the Y-width dimension. Further, portions of the first heat dissipater and the second heat dissipater can be routed along their respective voltage regulator component groupings and into the enlarged spacing and remain within a volumetric space 140 of the voltage regulator assembly, thereby resulting in a voltage regulator cooling solution that is low profile and able to fit within a tight space adjacent to a PCIe expansion card (not shown in FIG. 1). As an example, the PCIe expansion card can be a graphics card that is located in physical proximity to the voltage regulator and the voltage regulator cooling solution.

In the example shown in FIG. 1, the first heat dissipater 110 and the second heat dissipater 120 can be routed into the enlarged spacing 152 between a first voltage regulator component grouping 132 (which includes sub-groups 132A, 132B, and 132C) and a second voltage regulator component grouping 134 (which includes sub-groups 134A, 134B, and 134C), but this is not intended to be limiting. For example, the first heat dissipater and the second heat dissipater can be routed into an enlarged spacing between the second voltage regulator component grouping (shown) and a third voltage regulator component grouping (not shown in this example), or between a fourth voltage regulator component grouping and a fifth voltage regulator component grouping (not shown), and so forth. Furthermore, the various groupings of sub-groups could be a number other than the three (3) and three (3) sub-groups shown, e.g., 1 and 4, 2, and 5, 3 and 1, etc.

In one example, an average spacing 154 can exist between voltage regulator components of a voltage regulator component grouping of the voltage regulator 130. The first heat dissipater 110 and the second heat dissipater 120 are not routed in between this average individual component spacing. Rather, the first heat dissipater and the second heat dissipater can be routed between two voltage regulator component groupings being separated by the enlarged spacing 152. As an example, the enlarged spacing can be 3 to 30 times greater than the average spacing. Generally, the voltage regulator can have one enlarged spacing in which the first and/or second heat dissipaters can be routed between, however, in some examples, there may be other enlarged spacings between groupings where the first and/or second heat dissipater is routed.

In one example, the first voltage regulator component grouping 132 of the voltage regulator 130 and/or the second voltage regulator component grouping 134 can independently include various sub-groups (notated by 132A, 132B, 132C, 134A, 134B, and 134C). These various sub-groups can independently include various components, such as an inductor, a capacitor, a driver and a metal-oxide-semiconductor field-effect transistor (MOSFET). The individual voltage regulator component grouping can provide a portion of power to the processor. Notably, though there are three individual components (or sub-groups) shown in the two voltage regulator component groupings, there may be three, four, five, etc., e.g., from 2 to 7 individual components or sub-groups within the individual voltage regulator component groupings. As a non-limiting example, a given voltage regulator component grouping can include components or sub-groups of one or two capacitors, one inductor, one or two drivers, and/or one or two MOSFETs.

In one configuration, the first heat dissipater 110 can include a heat absorption end portion 112 and a heat rejection end portion 114. The heat absorption end portion can absorb heat generated by the voltage regulator 130 and the heat rejection end portion can dissipate or disperse heat generated by the voltage regulator into a surrounding environment. The heat absorption end portion can be within the volumetric space 140 of the voltage regulator assembly 100, whereas the heat rejection end portion can be outside of the volumetric space of the voltage regulator assembly. For example, the first heat dissipater can be routed into the enlarged space 152 and outside of the volumetric space, such that the heat rejection end portion can be outside the volumetric space. The first heat dissipater, after being routed outside of the volumetric space, can be bent and further directed in the Z-height dimension such that the heat rejection end portion is at an angle in relation to the heat absorption end portion. In one example, the heat rejection end portion can be perpendicular or orthogonal to the heat absorption end portion. In another example, the heat rejection end portion can be 45 degrees to 135 degrees from the heat absorption end portion.

In a specific example, the heat absorption end portion 112 of the first heat dissipater 110 can refer to an evaporation end, and the heat rejection end portion 114 of the first heat dissipater can refer to a condenser end. In this example, the heat absorption end portion can cause heat produced by the voltage regulator 130 to be absorbed and evaporate a liquid within the heat dissipater, where the heat can be carried through the first heat dissipater and removed to another location such as the heat rejection end portion, where the liquid can be condensed, dissipating the heat to a surrounding environment.

Similarly, the second heat dissipater 120 can include a heat absorption end portion 122 and a heat rejection end portion 124. The heat absorption end portion can be within the volumetric space 140 of the voltage regulator assembly 100, whereas the heat rejection end portion can be outside of the volumetric space of the voltage regulator assembly. For example, the second heat dissipater can be routed into the enlarged space 152 and outside of the volumetric space, such that the heat rejection end portion can be outside the volumetric space. The second heat dissipater, after being routed outside of the volumetric space, can be bent and further directed in the Z-height dimension such that the heat rejection end portion is at an angle in relation to the heat absorption end portion. In one example, the heat rejection end portion can be perpendicular or orthogonal to the heat absorption end portion. In another example, the heat rejection end portion can be 45 degrees to 135 degrees from the heat absorption end portion.

In one example, a Z-height dimension of the first and second heat dissipaters 110, 120 can be less than or equal to Z-height dimensions of the voltage regulator component groupings in the voltage regulator 130. In other words, the Z-height dimension of the first and second heat dissipaters can be less than or equal to the Z-height dimensions of the inductor, capacitor, driver and MOSFET that form an individual voltage regulator component grouping in the voltage regulator.

In one example, the heat absorption end portion 112 of the first heat dissipater 110 and the heat absorption end portion 122 of the second heat dissipater 120 can be located at opposite ends of the voltage regulator 130, and the first heat dissipater and the second heat dissipater can be directed along opposite voltage regulator component groupings and meet at the enlarged spacing 152, before being respectively routed through the enlarged spacing and outside of the volumetric space 140 of the voltage regulator assembly 100. Thus, the first and second heat dissipaters can initially be routed along the voltage regulator component groupings in the X-length dimension, and then through the enlarged spacing in the Y-width dimension, and then outside of the volumetric space in the Z-height direction. Further, the heat rejection end portion 114 and the heat rejection end portion 124 can be coupled to a fin stack or other cooling structure (not shown in FIG. 1).

In one example, the first heat dissipater 110 and the second heat dissipater 120 can be associated with a diameter 156. A combined diameter of the first heat dissipater and the second dissipater can be less than the enlarged spacing 152 between the voltage regulator component groupings. The diameter of the first and second heat dissipaters can vary depending on an amount of heat generated by the voltage regulator 130. For example, the diameter can be increased when the voltage regulator generates an increased amount of power and therefore produces an increased amount of heat, and the diameter can be reduced when the voltage regulator generates a reduced amount of power and therefore produces a reduced amount of heat. Therefore, a dimension of the enlarged spacing between the voltage regulator component groupings can depend on the diameters of the first and second heat dissipaters.

In a non-limiting example, the enlarged spacing 152 between the voltage regulator component groupings can be 15 millimeters (mm), and the diameter 156 of the first heat dissipater 110 can be 6 mm and the diameter of the second heat dissipater can be 6 mm. Therefore, the enlarged spacing is sufficient for both the first and second heat dissipaters to be directed through the enlarged spacing. In this example, the first and second heat dissipaters may touch each other, or alternatively, the first and second heat dissipaters can be separated by 1 mm, 2 mm or 3 mm, such that the first and second heat dissipaters are within the 15 mm dimension of the enlarged spacing. Further, in another example, a Z-height dimension between a bottom surface of the voltage regulator 130 and a bottom surface of the PCIe expansion card can be 13 mm. In other words, in this example, the volumetric space 140 can have a Z-height dimension that is equal to 13 mm, and a Z-height dimension of the components (e.g., the inductor, capacitor, driver and MOSFET) in the voltage regulator component groupings as well as a Z-height dimension of the first and second heat dissipaters can be less than or equal to 13 mm. Further, in yet another example, the first and second heat dissipaters can enable support for high power processors (e.g., 350 watts or more) as well as overclocking.

In the example shown in FIG. 2, the first and second heat dissipaters 110, 120 can be within the Z-height dimension of the volumetric space 140, minus the heat rejection end portion 114 and the heat rejection end portion 124 of the first and second heat dissipaters, respectively. Therefore, the voltage regulator cooling solution described herein can accommodate the reduced-size dimensions between the PCIe expansion card and a CPU.

In one example, one heat dissipater of increased width could be directed on top of the voltage regulator component groupings to provide a voltage regulator cooling solution, provided that there is sufficient spacing between the voltage regulator and a PCIe expansion card in proximity to the voltage regulator. However, with the reduced size dimensions between the PCIe expansion card and a CPU found in recent processor configurations, such a configuration would not be possible as the thickness of the single heat dissipater would be greater than an amount of space between the voltage regulator and the PCIe expansion card located adjacent to the voltage regulator.

FIG. 2 illustrates an example of a side view of a voltage regulator 130 and a heat dissipater 110 to draw heat away from the voltage regulator. The voltage regulator can provide power to a processor or CPU (not shown in FIG. 2). In this side view of the voltage regulator, a second heat dissipater is not viewable, but the second heat dissipater can be located behind the heat dissipater shown in FIG. 2. The voltage regulator can be coupled to a circuit board 260 (or motherboard). The voltage regulator can be positioned in between the circuit board and a PCIe expansion card 265, such as a graphics card. The voltage regulator can occupy a volumetric space 140 between the circuit board and the PCIe expansion card in a Z-height direction. In this side view of the voltage regulator, the Z-height dimension and a Y length dimension of the volumetric space is visible, and an X width dimension of the volumetric space is not visible.

In one example, the heat dissipater 110 can include a heat absorption end portion 112 and a heat rejection end portion 114. The heat absorption end portion can be within the volumetric space 140 of the voltage regulator 130. The heat dissipater can be routed in an X width dimension and then into an enlarged area along a Y length dimension. The heat dissipater, after being routed outside of the volumetric space, can be bent at a defined angle 262 and then routed in the Z-height dimension. In other words, the heat dissipater, after being routed outside of the volumetric space, can be bent and further directed in the Z-height dimension such that the heat rejection end portion is at the defined angle in relation to the heat absorption end portion. In one example, the heat rejection end portion can be perpendicular or orthogonal to the heat absorption end portion, when the defined angle is 90 degrees. In another example, the defined angle can be 45 degrees to 135 degrees, such that the heat rejection end portion can be non-coplanar relative to the heat absorption end portion. In yet another example, the defined angle can be between +90 degrees and −90 degrees, such that the heat rejection end portion can project downwards when at −90 degrees, upwards when at +90 degrees, or horizontal when at 0 degrees. The heat rejection end portion can draw heat generated from the voltage regulator away from the CPU, as well as away from the PCIe expansion card 265, as heat emitted from the heat rejection end portion could otherwise negatively affect performance of the PCIe expansion card.

As shown in FIG. 2, the heat absorption end portion 112 of the heat dissipater 110 can be within the volumetric space 140 of the voltage regulator 130 between the circuit board 260 and the PCIe expansion card 265. As a result, the heat dissipater can provide a voltage regulator cooling solution that is low profile and is compatible with recent processor configurations, in which PCIe expansion cards have been moved closer to CPU sockets to create a chassis that can fit as many PCIe expansion cards (e.g., graphics cards) as possible, for example. The low profile of the heat dissipater may not interfere with other components that are coupled to the circuit board, such as dual in-line memory modules (DIMMs), other slots or sockets, etc.

In the example shown in FIG. 2, the component shown in proximity to the voltage regulator 130 is the PCIe expansion card 265, and the heat dissipater 110 can be embedded within the voltage regulator and within the volumetric space 140 of the voltage regulator to fit between the circuit board 260 and the PCIe expansion card. However, in certain situations, the component that is in proximity to the voltage regulator can be different than a PCIe expansion card. Rather, the component can be another computer component or circuit board component that is located in physical proximity to the voltage regulator, and the heat dissipater can be routed to draw heat away from both the voltage regulator and the other computer component or circuit board component.

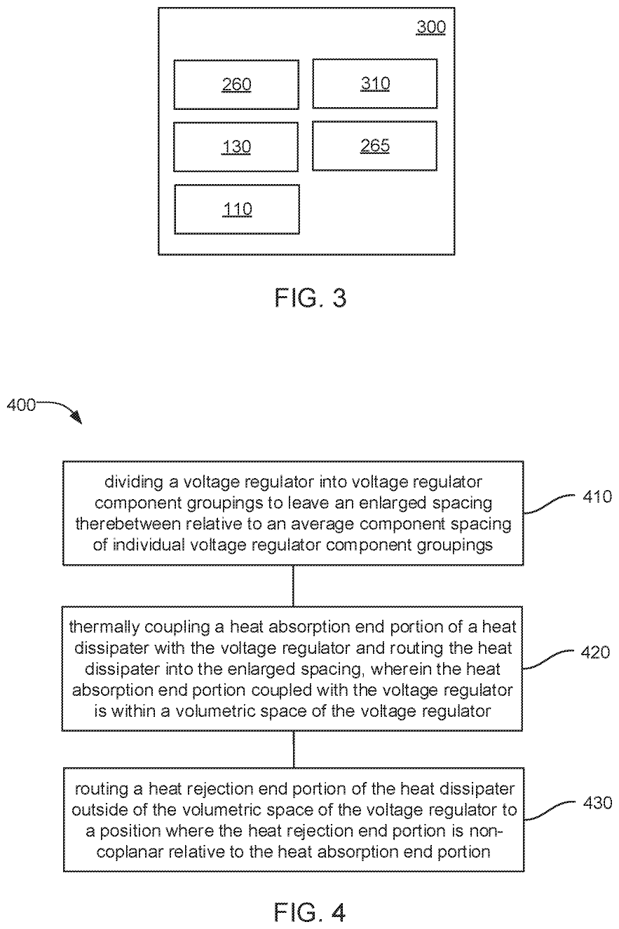

FIG. 3 illustrates an example of a system 300. The system can include a circuit board 260, a processor 310 coupled to the circuit board, and a voltage regulator 130 to provide power to the processor. The voltage regulator can occupy a volumetric space and includes voltage regulator component groupings within the volumetric space. The system can further include a PCIe expansion card 265 (e.g., a graphics card) coupled to the circuit board, as well as a heat dissipater 110. The heat dissipater can draw heat away from the voltage regulator and protect the PCIe expansion card. The volumetric space of the voltage regulator can occupy a space between the circuit board and the PCIe expansion card. The heat dissipater can include a heat absorption end portion thermally coupled to the voltage regulator, and the heat dissipater can be routed along the voltage regulator and into an enlarged spacing between the voltage regulator component groupings. Further, the heat absorption end portion of the heat dissipater can be positioned within the volumetric space of the voltage regulator, and the heat dissipater can include a heat rejection end portion that is routed outside of the volumetric space of the voltage regulator. The heat rejection end portion can be non-coplanar relative to the heat absorption end portion, or alternatively, the heat rejection end portion can be oriented orthogonally relative to the heat absorption end portion. Further, the heat absorption end portion of the heat dissipater within the volumetric space of the voltage regulator and the heat rejection end portion that is routed outside of the volumetric space may not interfere with the PCIe expansion card.

FIG. 4 is a flowchart illustrating one example method 400 of making a heat-dissipating voltage regulator assembly. The method can include dividing 410 a voltage regulator into voltage regulator component groupings to leave an enlarged spacing therebetween relative to an average component spacing of individual voltage regulator component groupings. The method further includes thermally coupling 420 a heat absorption end portion of a heat dissipater with the voltage regulator and routing the heat dissipater into the enlarged spacing, where the heat absorption end portion coupled with the voltage regulator can be within a volumetric space of the voltage regulator. The method can further include routing 430 a heat rejection end portion of the heat dissipater outside of the volumetric space of the voltage regulator to a position where the heat rejection end portion can be non-coplanar relative to the heat absorption end portion.

While the flowcharts presented for this disclosure can imply a specific order of execution, the order of execution can differ from what is illustrated. For example, the order of two or more blocks can be rearranged relative to the order shown. Further, two or more blocks shown in succession can be executed in parallel or with partial parallelization. In some configurations, block(s) shown in the flow chart can be omitted or skipped. A number of counters, state variables, warning semaphores, or messages can be added to the logical flow for purposes of enhanced utility, accounting, performance, measurement, troubleshooting or for similar reasons.

Although the subject matter has been described in language specific to structural features and/or operations, it is to be understood that the subject matter defined in the appended claims is not limited to the specific features and operations described above. Rather, the specific features and acts described above are disclosed as example forms of implementing the claims. Numerous modifications and alternative arrangements can be devised without departing from the scope of the described disclosure.

It is noted that, as used in this specification and the appended claims, the singular forms “a,” “an,” and “the” include plural referents unless the context clearly dictates otherwise.

As used herein, the term “about” is used to provide flexibility to a numerical range endpoint by providing that a given value may be “a little above” or “a little below” the endpoint. The degree of flexibility of this term can be dictated by the particular variable and determined based on the associated description herein.

As used herein, a plurality of items, structural elements, compositional elements, and/or materials may be presented in a common list for convenience. However, these lists should be construed as though individual members of the list are individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include the numerical values explicitly recited as the limits of the range, and also to include individual numerical values or sub-ranges encompassed within that range as if individual numerical values and sub-ranges are explicitly recited. As an illustration, a numerical range of “about 1 to about 20” should be interpreted to include the explicitly recited values of about 1 to about 20, and also to include individual values and sub-ranges within the indicated range. Thus, included in this numerical range are individual values such as 2, 3.5, 10, 15, and sub-ranges such as from 1-10, from 2-15, and from 10-20, etc. This same principle applies to ranges reciting a single numerical value. Furthermore, such an interpretation should apply regardless of the breadth of the range or the characteristics being described.

What is claimed is:

1. A voltage regulator assembly, comprising:
a voltage regulator to provide power to a processor, the voltage regulator occupying a volumetric space and including a voltage regulator component grouping within the volumetric space; and
a heat dissipater including a heat absorption end portion thermally coupled to the voltage regulator, the heat dissipater being routed along the voltage regulator and into an enlarged spacing between the voltage regulator component grouping,
wherein the heat absorption end portion of the heat dissipater is positioned within the volumetric space of the voltage regulator, and the heat dissipater includes a heat rejection end portion that is routed outside of the volumetric space of the voltage regulator.

2. The voltage regulator assembly of claim 1, further comprising a second heat dissipater including a second heat absorption end portion and a second heat rejection end portion, wherein the heat absorption end portion of the heat dissipater is routed along a first voltage regulator component grouping and the second heat absorption end portion of the second heat dissipater is routed along a second voltage regulator component grouping.

3. The voltage regulator assembly of claim 1, wherein an individual voltage regulator component grouping includes an inductor, a capacitor, a driver and a metal-oxide-semiconductor field-effect transistor (MOSFET), and the individual voltage regulator component grouping provides a portion of power to the processor and another individual voltage regulator component grouping provides a second portion of power to the processor.

4. The voltage regulator assembly of claim 1, wherein the voltage regulator component groupings independently include an average component spacing between individual voltage regulator components, wherein the enlarged spacing between the voltage regulator component groupings is from 3 to 30 times greater than the average component spacing.

5. The voltage regulator assembly of claim 1, wherein the volumetric space of the voltage regulator is adjacent to a Peripheral Component Interconnect Express (PCIe) expansion card, and the heat absorption end portion of the heat dissipater within the volumetric space of the voltage regulator and the heat rejection end portion that is routed outside of the volumetric space does not interfere with the PCIe expansion card.

6. The voltage regulator assembly of claim 1, wherein the heat rejection end portion is oriented orthogonally relative to the heat absorption end portion.

7. A system, comprising:
a circuit board;
a processor coupled to the circuit board;
a voltage regulator to provide power to the processor, the voltage regulator occupying a volumetric space and including a first voltage regulator component grouping and a second voltage regulator component grouping within the volumetric space; and
a heat dissipater to draw heat away from the voltage regulator and protect a graphics card configured to be coupled to the circuit board, the heat dissipater routed along the voltage regulator and into an enlarged spacing between the first voltage regulator component grouping and the second voltage regulator component grouping, wherein the heat dissipater includes a heat absorption end portion thermally coupled to the voltage regulator and is within the volumetric space of the voltage regulator which is adjacent to the graphics card, and the heat dissipater also includes a heat rejection end portion that is routed outside of the volumetric space of the voltage regulator, wherein the heat rejection end portion is non-coplanar relative to the heat absorption end portion.

8. The system of claim 7, further comprising a second heat dissipater including a second heat absorption end portion and a second heat rejection end portion, wherein the heat absorption end portion of the heat dissipater is routed along the first voltage regulator component grouping and the second heat absorption end portion of the second heat dissipater is routed along the second voltage regulator component grouping.

9. The system of claim 7, wherein the first and second voltage regulator component groupings independently include an average component spacing between individual voltage regulator components, wherein the enlarged spacing between the first and second voltage regulator component groupings is from 3 to 30 times greater than the average component spacing.

10. The system of claim 7, wherein the volumetric space of the voltage regulator occupies a space between the circuit board and the graphics card.

11. The system of claim 7, wherein the heat rejection end portion is oriented orthogonally relative to the heat absorption end portion.

12. A method of making a heat-dissipating voltage regulator assembly, comprising:
dividing a voltage regulator into voltage regulator component groupings to leave an enlarged spacing therebetween relative to an average component spacing of individual voltage regulator component groupings;
thermally coupling a heat absorption end portion of a heat dissipater with the voltage regulator and routing the heat dissipater into the enlarged spacing, wherein the heat absorption end portion coupled with the voltage regulator is within a volumetric space of the voltage regulator; and
routing a heat rejection end portion of the heat dissipater outside of the volumetric space of the voltage regulator to a position where the heat rejection end portion is non-coplanar relative to the heat absorption end portion.

13. The method of claim 12, further comprising:
thermally coupling a second heat absorption end portion of a second heat dissipater with the voltage regulator and routing the second heat dissipater into the enlarged spacing, wherein the second heat absorption end portion coupled with the voltage regulator is within the volumetric space of the voltage regulator; and
routing a second heat rejection end portion of the second heat dissipater outside of the volumetric space of the voltage regulator to a position where the second heat rejection end portion is non-coplanar relative to the second heat absorption end portion.

14. The method of claim 12, wherein the enlarged spacing is from 3 to 30 times greater than the average component spacing of the individual voltage regulator component groupings.

15. The method of claim 12, further comprising positioning the voltage regulator so that the volumetric space of the voltage regulator occupies a space between a circuit board and a Peripheral Component Interconnect Express (PCIe) expansion card.
